(19) United States
(12) Patent Application Publication
(10) Pub. No.: US 2016/0258075 A1
(43) Pub. Date: Sep. 8, 2016

(54) Method of Forming Electrically Isolated Structures Using Thin Dielectric Coatings

(71) Applicant: Microfabrica Inc., Van Nuys, CA (US)

(72) Inventors: Dennis R. Smalley, Newhall, CA (US); Adam L. Cohen, Dallas, TX (US); Ananda H. Kumar, Fremont, CA (US); Michael S. Lockard, Lake Elizabeth, CA (US)

(73) Assignee: Microfabrica Inc., Van Nuys, CA (US)

(21) Appl. No.: 15/091,537

(22) Filed: Apr. 5, 2016

Related U.S. Application Data
(63) Continuation of application No. 13/657,375, filed on Oct. 22, 2012, now abandoned.
Application No. 13/657,375 is a continuation of application No. 12/506,547, filed on Jul. 21, 2009, now abandoned.
Application No. 12/506,547 is a continuation of application No. 11/325,405, filed on Jan. 3, 2006, now abandoned.
(60) Provisional application No. 60/641,292, filed on Jan. 3, 2005.

(51) Int. Cl. C25D 1/00; H05K 3/46; C25D 1/20

(52) U.S. Cl. CPC C25D 1/003; C25D 1/20; H05K 3/467; H05K 3/4682

(57) ABSTRACT

Electrochemical fabrication processes and apparatus for producing multi-layer structures where each layer includes the deposition of at least two materials and wherein the formation of at least some layers including operations for providing coatings of dielectric material that isolate at least portions of a first conductive material from (1) other portions of the first conductive material, (2) a second conductive material, or (3) another dielectric material, and wherein the thickness of the dielectric coatings are thin compared to the thicknesses of the layers used in forming the structures. In some preferred embodiments, portions of each individual layer are encapsulated by dielectric material while in other embodiments only boundaries between distinct regions of materials are isolated from one another by dielectric barriers.

### RELATED APPLICATIONS

This application is a continuation of U.S. patent application Ser. No. 13/657,375 (P-US152-C-MF), filed Oct. 22, 2012. The '375 application is a continuation of U.S. patent application Ser .No. 12/506,547 (P-US152-B-MF), filed Jul. 21, 2009. The '547 application is a continuation of U.S. patent application Ser. No. 11/325,405 (P-US152-A-MF), filed Jan. 3, 2006. The '405 application claims benefit of U.S. Provisional Patent Application No. 60/641,292, filed Jan. 3, 2005 and is a continuation in part of U.S. patent application Ser. No. 11/029,221 (P-US138-A-MF), filed Jan. 3, 2005, now U.S. Pat. No. 7,531,077, issued on May 12, 2009. The '221 application in turn claims benefit of U.S. Provisional Patent Application Nos. 60/533,897, 60/533,975, 60/533,947, 60/533,948, each filed on Dec. 31, 2003; and of 60/540,510, filed Jan. 29, 2004. The '221 application is also a continuation in part of U.S. patent application Ser. No. 10/949,738 (P-US119-A-MF), filed Sep. 24, 2004. The '738 application is a continuation in part of U.S. patent application Ser. No. 10/772,943 (P-US097-A-MF), filed Feb. 4, 2004, which in turn claims benefit of U.S. Provisional Patent Application No. 60/445,186, filed Feb. 4, 2003. Both of the '738 and the '943 applications claim benefit of U.S. Provisional Application Nos. 60/506,015, filed Sep. 24, 2003; 60/533,933, filed Dec. 31, 2003, and 60/536,865, filed Jan. 15, 2004. Each of these applications, including any appendices attached thereto, is incorporated herein by reference as if set forth in full herein.

### FIELD OF THE INVENTION

Embodiments of this invention relate to the field of electrochemical fabrication and the associated formation of multi-layer three-dimensional structures and more specifically to processes for forming structures that include dielectric coatings that are thin compared to the layer thickness (e.g. less than about ½ the layer thickness, more preferably less than about ¼ the layer thickness, and most preferably less than about 1/10 the layer thickness) that defines the general features of the structures that are being formed (e.g. that are set by the thickness between successive planarization operations that are used in forming the structures) and that provide desired electrical isolation of conductive elements of the structures.

### BACKGROUND OF THE INVENTION

A technique for forming three-dimensional structures (e.g. parts, components, devices, and the like) from a plurality of adhered layers was invented by Adam L. Cohen and is known as Electrochemical Fabrication. Variations of this process are being commercially pursued by Microfabrica Inc. of Van Nuys, Calif. under the name MICA FREEFORM® (formerly EFAB®). This technique was described in U.S. Pat. No. 6,027,630, issued on Feb. 22, 2000. This electrochemical deposition technique allows the selective deposition of a material using a unique masking technique that involves the use of a mask that includes patterned conformable material on a support structure that is independent of the substrate onto which plating will occur. When desiring to perform an electrodeposition using the mask, the conformable portion of the mask is brought into contact with a substrate while in the presence of a plating solution such that the contact of the conformable portion of the mask to the substrate inhibits deposition at selected locations. For convenience, these masks might be generically called conformable contact masks; the masking technique may be generically called a conformable contact mask plating process. More specifically, in the terminology of Microfabrica Inc. of Van Nuys, Calif. such masks have come to be known as INSTANT MASKS™ and the process known as INSTANT MASKING™ or INSTANT MASK™ plating. Selective depositions using conformable contact mask plating may be used to form single layers of material or may be used to form multi-layer structures. The teachings of the '630 patent are hereby incorporated herein by reference as if set forth in full herein. Since the filing of the patent application that led to the above noted patent, various papers about conformable contact mask plating (i.e. INSTANT MASKING™) and electrochemical fabrication have been published:
1. A. Cohen, G. Zhang, F. Tseng, F. Mansfeld, U. Frodis and P. Will, “EFAB: Batch production of functional, fully-dense metal parts with micro-scale features”, Proc. 9th Solid Freeform Fabrication, The University of Texas at Austin, p 161, August 1998.
2. A. Cohen, G. Zhang, F. Tseng, F. Mansfeld, U. Frodis and P. Will, “EFAB: Rapid, Low-Cost Desktop Micromachining of High Aspect Ratio True 3-D MEMS”, Proc. 12th IEEE Micro Electro Mechanical Systems Workshop, IEEE, p 244, January 1999.
3. A. Cohen, “3-D Micromachining by Electrochemical Fabrication”, Micromachine Devices, March 1999.
4. G. Zhang, A. Cohen, U. Frodis, F. Tseng, F. Mansfeld, and P. Will, “EFAB: Rapid Desktop Manufacturing of True 3-D Microstructures”, Proc. 2nd International Conference on Integrated MicroNanotechnology for Space Applications, The Aerospace Co., April 1999.
5. F. Tseng, U. Frodis, G. Zhang, A. Cohen, F. Mansfeld, and P. Will, “EFAB: High Aspect Ratio, Arbitrary 3-D Metal Microstructures using a Low-Cost Automated Batch Process”, 3rd International Workshop on High Aspect Ratio MicroStructure Technology (HARMST'99), June 1999.
6. A. Cohen, U. Frodis, F. Tseng, G. Zhang, F. Mansfeld, and P. Will, “EFAB: Low-Cost, Automated Electrochemical Batch Fabrication of Arbitrary 3-D Microstructures”, Micromachining and Microfabrication Process Technology, SPIE 1999 Symposium on Micromachining and Microfabrication, September 1999.
7. F. Tseng, G. Zhang, U. Frodis, A. Cohen, F. Mansfeld, and P. Will, “EFAB: High Aspect Ratio, Arbitrary 3-D Metal Microstructures using a Low-Cost Automated Batch Process”, MEMS Symposium, ASME 1999 International Mechanical Engineering Congress and Exposition, November, 1999.
8. A. Cohen, “Electrochemical Fabrication (EFAB™)”, Chapter 19 of The MEMS Handbook, edited by Mohamed Gad-El-Hak, CRC Press, 2002.
9. “Microfabrication—Rapid Prototyping's Killer Application”, pages 1-5 of the Rapid Prototyping Report, CAD/CAM Publishing, Inc., June 1999.

The disclosures of these nine publications are hereby incorporated herein by reference as if set forth in full herein.

The electrochemical deposition process may be carried out in a number of different ways as set forth in the above patent and publications. In one form, this process involves the execution of three separate operations during the formation of each layer of the structure that is to be formed:
1. Selectively depositing at least one material by electrodeposition upon one or more desired regions of a substrate.
2. Then, blanket depositing at least one additional material by electrodeposition so that the additional deposit covers both the regions that were previously selectively deposited onto, and the regions of the substrate that did not receive any previously applied selective depositions.
3. Finally, planarizing the materials deposited during the first and second operations to produce a smoothed surface of a first layer of desired thickness having at least one region containing the at least one material and at least one region containing at least the one additional material.

After formation of the first layer, one or more additional layers may be formed adjacent to the immediately preceding layer and adhered to the smoothed surface of that preceding layer. These additional layers are formed by repeating the first through third operations one or more times wherein the formation of each subsequent layer treats the previously formed layers and the initial substrate as a new and thickening substrate.

Once the formation of all layers has been completed, at least a portion of at least one of the materials deposited is generally removed by an etching process to expose or release the three-dimensional structure that was intended to be formed.

The preferred method of performing the selective electrodeposition involved in the first operation is by conformable contact mask plating. In this type of plating, one or more conformable contact (CC) masks are first formed. The CC masks include a support structure onto which a patterned conformable dielectric material is adhered or formed. The conformable material for each mask is shaped in accordance with a particular cross-section of material to be plated. At least one CC mask is needed for each unique cross-sectional pattern that is to be plated.

The support for a CC mask is typically a plate-like structure formed of a metal that is to be selectively electroplated and from which material to be plated will be dissolved. In this typical approach, the support will act as an anode in an electroplating process. In an alternative approach, the support may instead be a porous or otherwise perforated material through which deposition material will pass during an electroplating operation on its way from a distal anode to a deposition surface. In either approach, it is possible for CC masks to share a common support, i.e. the patterns of conformable dielectric material for plating multiple layers of material may be located in different areas of a single support structure. When a single support structure contains multiple plating patterns, the entire structure is referred to as the CC mask while the individual plating masks may be referred to as “submasks”. In the present application such a distinction will be made only when relevant to a specific point being made.

In preparation for performing the selective deposition of the first operation, the conformable portion of the CC mask is placed in registration with and pressed against a selected portion of the substrate (or onto a previously formed layer or onto a previously deposited portion of a layer) on which deposition is to occur. The pressing together of the CC mask and substrate occur in such a way that all openings, in the conformable portions of the CC mask contain plating solution. The conformable material of the CC mask that contacts the substrate acts as a barrier to electrodeposition while the openings in the CC mask that are filled with electroplating solution act as pathways for transferring material from an anode (e.g. the CC mask support) to the non-contacted portions of the substrate (which act as a cathode during the plating operation) when an appropriate potential and/or current are supplied.

An example of a CC mask and CC mask plating are shown in FIGS. 1A - 1C. FIG. 1 A shows a side view of a CC mask 8 consisting of a conformable or deformable (e.g. elastomeric) insulator 10 patterned on an anode 12. The anode has two functions. One is as a supporting material for the patterned insulator 10 to maintain its integrity and alignment since the pattern may be topologically complex (e.g., involving isolated “islands” of insulator material). The other function is as an anode for the electroplating operation. FIG. 1A also depicts a substrate 6 separated from mask 8. CC mask plating selectively deposits material 22 onto a substrate 6 by simply pressing the insulator against the substrate then electrodepositing material through apertures 26a and 26b in the insulator as shown in FIG. 1B. After deposition, the CC mask is separated, preferably non-destructively, from the substrate 6 as shown in FIG. 1C. The CC mask plating process is distinct from a “through-mask” plating process in that in a through-mask plating process the separation of the masking material from the substrate would occur destructively. As with through-mask plating, CC mask plating deposits material selectively and simultaneously over the entire layer. The plated region may consist of one or more isolated plating regions where these isolated plating regions may belong to a single structure that is being formed or may belong to multiple structures that are being formed simultaneously. In CC mask plating as individual masks are not intentionally destroyed in the removal process, they may be usable in multiple plating operations.

Another example of a CC mask and CC mask plating is shown in FIGS. 1D-1G. FIG. 1D shows an anode 12′ separated from a mask 8′ that includes a patterned conformable material 10′ and a support structure 20. FIG. 1D also depicts substrate 6 separated from the mask 8′. FIG. 1E illustrates the mask 8′ being brought into contact with the substrate 6. FIG. 1F illustrates the deposit 22′ that results from conducting a current from the anode 12′ to the substrate 6. FIG. 1G illustrates the deposit 22′ on substrate 6 after separation from mask 8′. In this example, an appropriate electrolyte is located between the substrate 6 and the anode 12′ and a current of ions coming from one or both of the solution and the anode are conducted through the opening in the mask to the substrate where material is deposited. This type of mask may be referred to as an anodeless INSTANT MASK™ (AIM) or as an anodeless conformable contact (ACC) mask.

Unlike through-mask plating, CC mask plating allows CC masks to be formed completely separate from the fabrication of the substrate on which plating is to occur (e.g. separate from a three-dimensional (3D) structure that is being formed). CC masks may be formed in a variety of ways, for example, a photolithographic process may be used. All masks can be generated simultaneously prior to structure fabrication rather than during it. This separation makes possible a simple, low-cost, automated, self-contained, and internally-clean “desktop factory” that can be installed almost anywhere to fabricate 3D structures, leaving any required clean room processes, such as photolithography to be performed by service bureaus or the like.

An example of the electrochemical fabrication process discussed above is illustrated in FIGS. 2A-2F. These figures show that the process involves deposition of a first material 2 which is a sacrificial material and a second material 4 which is a structural material. The CC mask 8, in this example, includes a patterned conformable material (e.g. an elastomeric dielectric material) 10 and a support 12 which is made from deposition material 2. The conformal portion of the CC mask is pressed against substrate 6 with a plating solution 14 located within the openings 16 in the conformable material 10. An electric current, from power supply 18, is then passed through the plating solution 14 via (a) support 12 which doubles as an anode and (b) substrate 6 which doubles as a cathode. FIG. 2A illustrates that the passing of current causes material 2 within the plating solution and material 2 from the anode 12 to be selectively transferred to and plated on the substrate 6. After electroplating the first deposition material 2 onto the substrate 6 using CC mask 8, the CC mask 8 is removed as shown in FIG. 2B. FIG. 2C depicts the second deposition material 4 as having been blanket-deposited (i.e. non-selectively deposited) over the previously deposited first deposition material 2 as well as over the other portions of the substrate 6. The blanket deposition occurs by electroplating from an anode (not shown), composed of the second material, through an appropriate plating solution (not shown), and to the cathode/substrate 6. The entire two-material layer is then planarized to achieve precise thickness and flatness as shown in FIG. 2D. After repetition of this process for all layers, the multi-layer structure 20 formed of the second material 4 (i.e. structural material) is embedded in first material 2 (i.e. sacrificial material) as shown in FIG. 2E. The embedded structure is etched to yield the desired device, i.e. structure 20, as shown in FIG. 2F.

Various components of an exemplary manual electrochemical fabrication system 32 are shown in FIGS. 3A-3C. The system 32 consists of several subsystems 34, 36, 38, and 40. The substrate holding subsystem 34 is depicted in the upper portions of each of FIGS. 3A-3C and includes several components: (1) a carrier 48, (2) a metal substrate 6 onto which the layers are deposited, and (3) a linear slide 42 capable of moving the substrate 6 up and down relative to the carrier 48 in response to drive force from actuator 44. Subsystem 34 also includes an indicator 46 for measuring differences in vertical position of the substrate which may be used in setting or determining layer thicknesses and/or deposition thicknesses. The subsystem 34 further includes feet 68 for carrier 48 which can be precisely mounted on subsystem 36.

The CC mask subsystem 36 shown in the lower portion of FIG. 3A includes several components: (1) a CC mask 8 that is actually made up of a number of CC masks (i.e. submasks) that share a common support/anode 12, (2) precision X-stage 54, (3) precision Y-stage 56, (4) frame 72 on which the feet 68 of subsystem 34 can mount, and (5) a tank 58 for containing the electrolyte 16. Subsystems 34 and 36 also include appropriate electrical connections (not shown) for connecting to an appropriate power source (not shown) for driving the CC masking process.

The blanket deposition subsystem 38 is shown in the lower portion of FIG. 3B and includes several components: (1) an anode 62, (2) an electrolyte tank 64 for holding plating solution 66, and (3) frame 74 on which feet 68 of subsystem 34 may sit. Subsystem 38 also includes appropriate electrical connections (not shown) for connecting the anode to an appropriate power supply (not shown) for driving the blanket deposition process.

The planarization subsystem 40 is shown in the lower portion of FIG. 3C and includes a lapping plate 52 and associated motion and control systems (not shown) for planarizing the depositions.

In addition to teaching the use of CC masks for electrodeposition purposes, the '630 patent also teaches that the CC masks may be placed against a substrate with the polarity of the voltage reversed and material may thereby be selectively removed from the substrate. It indicates that such removal processes can be used to selectively etch, engrave, and polish a substrate, e.g., a plaque.

The '630 patent further indicates that the electroplating methods and articles disclosed therein allow fabrication of devices from thin layers of materials such as, e.g., metals, polymers, ceramics, and semiconductor materials. It further indicates that although the electroplating embodiments described therein have been described with respect to the use of two metals, a variety of materials, e.g., polymers, ceramics and semiconductor materials, and any number of metals can be deposited either by the electroplating methods therein, or in separate processes that occur throughout the electroplating method. It indicates that a thin plating base can be deposited, e.g., by sputtering, over a deposit that is insufficiently conductive (e.g., an insulating layer) so as to enable subsequent electroplating. It also indicates that multiple support materials (i.e. sacrificial materials) can be included in the electroplated element allowing selective removal of the support materials.

Another method for forming microstructures from electroplated metals (i.e. using electrochemical fabrication techniques) is taught in U.S. Pat. No. 5,190,637 to Henry Guckel, entitled “Formation of Microstructures by Multiple Level Deep X-ray Lithography with Sacrificial Metal layers”. This patent teaches the formation of metal structure utilizing mask exposures. A first layer of a primary metal is electroplated onto an exposed plating base to fill a void in a photoresist, the photoresist is then removed and a secondary metal is electroplated over the first layer and over the plating base. The exposed surface of the secondary metal is then machined down to a height which exposes the first metal to produce a flat uniform surface extending across the both the primary and secondary metals. Formation of a second layer may then begin by applying a photoresist layer over the first layer and then repeating the process used to produce the first layer. The process is then repeated until the entire structure is formed and the secondary metal is removed by etching. The photoresist is formed over the plating base or previous layer by casting and the voids in the photoresist are formed by exposure of the photoresist through a patterned mask via X-rays or UV radiation.

The '637 patent teaches the locating of a plating base onto a substrate in preparation for electroplating materials onto the substrate. The plating base is indicated as typically involving the use of a sputtered film of an adhesive metal, such as chromium or titanium, and then a sputtered film of the metal that is to be plated. It is also taught that the plating base may be applied over an initial sacrificial layer of material on the substrate so that the structure and substrate may be detached if desired. In such cases after formation of the structure the plating base may be patterned and removed from around the structure and then the sacrificial layer under the plating base may be dissolved to free the structure. Substrate materials mentioned in the '637 patent include silicon, glass, metals, and silicon with protected processed semiconductor devices. A specific example of a plating base includes about 150 angstroms of titanium and about 300 angstroms of nickel, both of which are sputtered at a temperature of 160° C. In another example it is indicated that the plating base may consist of 150 angstroms of titanium and 150 angstroms of nickel where both are applied by sputtering.

Even though electrochemical fabrication as taught and practiced to date, has greatly enhanced the capabilities of microfabrication, and in particular added greatly to the number of metal layers that can be incorporated into a structure and to the speed and simplicity in which such structures can be made, and even to the incorporation of some dielectric materials, room for enhancing dielectric incorporation and/or building on dielectric substrates exists.

### SUMMARY OF THE INVENTION

It is an object of some embodiments of the invention to provide an enhanced electrochemical fabrication process capable of forming structures including electrically isolated regions via use of thin dielectric coatings.

It is an object of some embodiments of the invention to provide electrochemically fabricated structures that have improved electrical characteristics.

Other objects and advantages of various embodiments of the invention will be apparent to those of skill in the art upon review of the teachings herein. The various embodiments of the invention, set forth explicitly herein or otherwise ascertained from the teachings herein, may address one or more of the above objects alone or in combination, or alternatively may address some other object of the invention ascertained from the teachings herein. It is not necessarily intended that all objects be addressed by any single aspect of the invention even though that may be the case with regard to some aspects.

A first aspect of the invention provides a method for forming a three dimensional structure from a plurality of adhered layers, comprising: forming a plurality of layers with each comprising regions of a first conductive material and regions of a filler material, wherein regions of the first conductive material and regions of the filler material are conductively isolated from one another by a dielectric material and wherein at least one of the following conditions is met: (A) the dielectric material is deposited during the forming of each of the plurality of layers and which has a coating thickness less than a layer thickness; (B) the dielectric material is (i) not located between those portions of two consecutive layers where the filler material on an upper layer overlies filler material on a lower layer and (ii) not located between portions of two consecutive layers where the first conductive material on the upper layer overlies the first conductive material on the lower layer; (C) the dielectric material separates those portions of two consecutive layers where the filler material on the upper layer overlies the filler material on the lower layer; (D) the dielectric material is located in interface regions between up-facing regions of the first conductive material and down-facing regions of the filler material; or (E) the dielectric material is located in interface regions between up-facing regions of filler material and down-facing regions of the first conductive material.

A second aspect of the invention provides a fabrication method for forming a multi-layer three-dimensional structure, comprising: (a) forming a first layer of the multi-layer structure, wherein the first layer comprises at least two materials; (b) forming a plurality of successive layers of the structure with each successive layer adhered to a previously formed layer to build up the three-dimensional structure, where the forming of each of the plurality of successive layers comprises at least two deposition operations that deposit at least two materials, which may be the same or different from the materials deposited on a previously formed layer, and at least one planarization operation; wherein the forming of at least a portion of the plurality of layers comprises the deposition of at least a thin coating material, that is different from the at least two materials, that at least partially encapsulates one of the at least two materials.

A third aspect of the invention provides a method for forming a multi-layer three-dimensional structure, comprising: (a) forming a first layer of the multi-layer structure, wherein the first layer comprises at least two materials; (b) forming a plurality of successive layers of the structure with each successive layer adhered to a previously formed layer to build up the three-dimensional structure, where the forming of each of the plurality of successive layers comprises at least three deposition operations that deposit at least three materials, which may be the same or different from the materials deposited on a previously formed layer, and at least one planarization operation, wherein one of the deposited materials is a sacrificial material and two of deposited materials are structural materials; and (c) after formation of the plurality of successive layers, removing at least a portion of the sacrificial material to release the structural material; wherein at least one of the structural material forms thin coatings over at least a portions of the surfaces of the other of the structural material.

A fourth aspect of the invention provides a method for forming a multi-layer three-dimensional structure, comprising: (a) forming a first layer of the multi-layer structure, wherein the first layer comprises at least two materials; (b) forming a plurality of successive layers of the structure with each successive layer adhered to a previously formed layer to build up the three-dimensional structure, where the forming of each of the plurality of successive layers comprises at least three deposition operations that deposit at least three materials, which may be the same or different from the materials deposited on a previously formed layer, and at least one planarization operation, wherein the formation of at least a portion of the plurality of layers comprises the deposition of at least two structural materials, a first of which encapsulates a second wherein the encapsulating first material does not completely isolate regions the second material on successive layers when those regions of second material at least partially intersect.

Further aspects of the invention will be understood by those of skill in the art upon reviewing the teachings herein. Other aspects of the invention may involve apparatus that can be used in implementing one or more of the above process aspects of the invention or devices formed using one of the above process aspects of the invention. These other aspects of the invention may provide various combinations of the aspects, embodiments, and associated alternatives explicitly set forth herein as well as provide other configurations, structures, functional relationships, and processes that have not been specifically set forth above.

### BRIEF DESCRIPTION OF THE DRAWINGS

FIGS. 1A-1C schematically depict side views of various stages of a CC mask plating process, while FIGS. 1D-1G schematically depict a side views of various stages of a CC mask plating process using a different type of CC mask.

FIGS. 2A-2F schematically depict side views of various stages of an electrochemical fabrication process as applied to the formation of a particular structure where a sacrificial material is selectively deposited while a structural material is blanket deposited.

FIGS. 3A-3C schematically depict side views of various example subassemblies that may be used in manually implementing the electrochemical fabrication method depicted in FIGS. 2A-2F.

FIGS. 4A-4F schematically depict the formation of a first layer of a structure using adhered mask plating where the blanket deposition of a second material overlays both the openings between deposition locations of a first material and the first material itself.

FIG. 4G depicts the completion of formation of the first layer resulting from planarizing the deposited materials to a desired level.

FIGS. 4H and 4I respectively depict the state of the process after formation of the multiple layers of the structure and after release of the structure from the sacrificial material.

FIG. 5 provides a side view an example structure which may be formed using a conductive material and dielectric material.

FIG. 6 provides a side view of a section of the structure of FIG. 5 and how it may look after being formed according to an embodiment of the present invention where thin coatings of dielectric material are provided in a way that encapsulates and electrically isolates conductive structural material from a filler material.

FIG. 7 provides a side view of a section of the same structure of FIGS. 5 and 6 but with the thin coatings or barriers of dielectric material provided only where necessary to electrically isolate the two other materials forming the structure from contacting each other while also isolating one of the materials from the substrate.

FIG. 8 depicts an example similar to that of FIG. 6 with the exception that the ends of the layers of one of the materials are capped with a dielectric material.

FIG. 9 depicts an example similar to that of FIG. 7 with the exception that the ends of the layers of one of the materials are capped with a dielectric material.

FIG. 10 provides a flowchart of an embodiment of the invention which allows the formation of metal structures using thin coatings of dielectric material where the top coating of dielectric material for a given layer is obtained from a patterned photoresist which is temporarily located on top of an otherwise completed and planarized layer.

FIG. 11 provides a flowchart of another embodiment of the invention which allows the formation of metal structures using thin coatings of dielectric material where the top coating of dielectric material for a given layer is obtained from blanket deposited dielectric material over which a masking material is applied and patterned and then undesired portions of the dielectric material removed.

FIG. 12 provides a flowchart of another embodiment of the invention which allows the formation of metal structures using thin coatings of dielectric material where the top coating of dielectric material for one of the materials for a given layer is applied only when that material of the given layer will not be automatically covered in its entirety by formation of the next layer.

FIGS. 13A-13W illustrate the operations of the process of FIG. 10 as applied to formation of the structure of FIG. 5 with the resulting structure being shown in FIG. 13W and with the resulting structure approximating the structure shown in FIG. 6.

FIGS. 14A-14B provide examples of first and second regions while FIGS. 14C and 14D provide Boolean differences between the first and second regions and the second and first regions, respectively.

### DETAILED DESCRIPTION

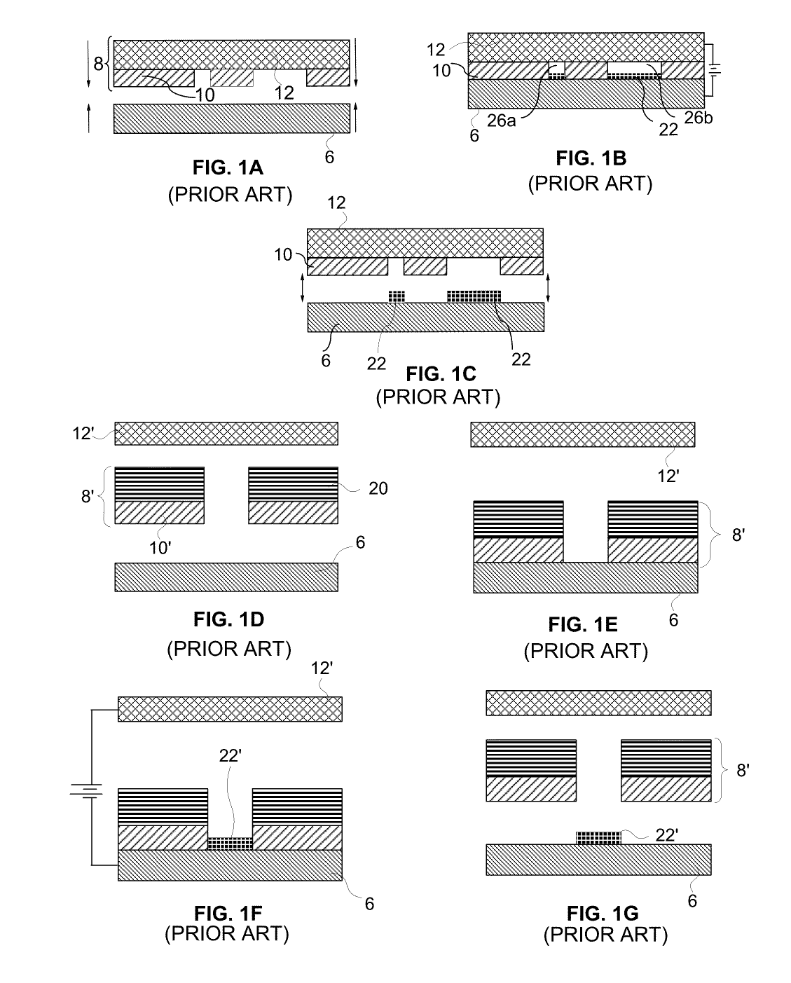

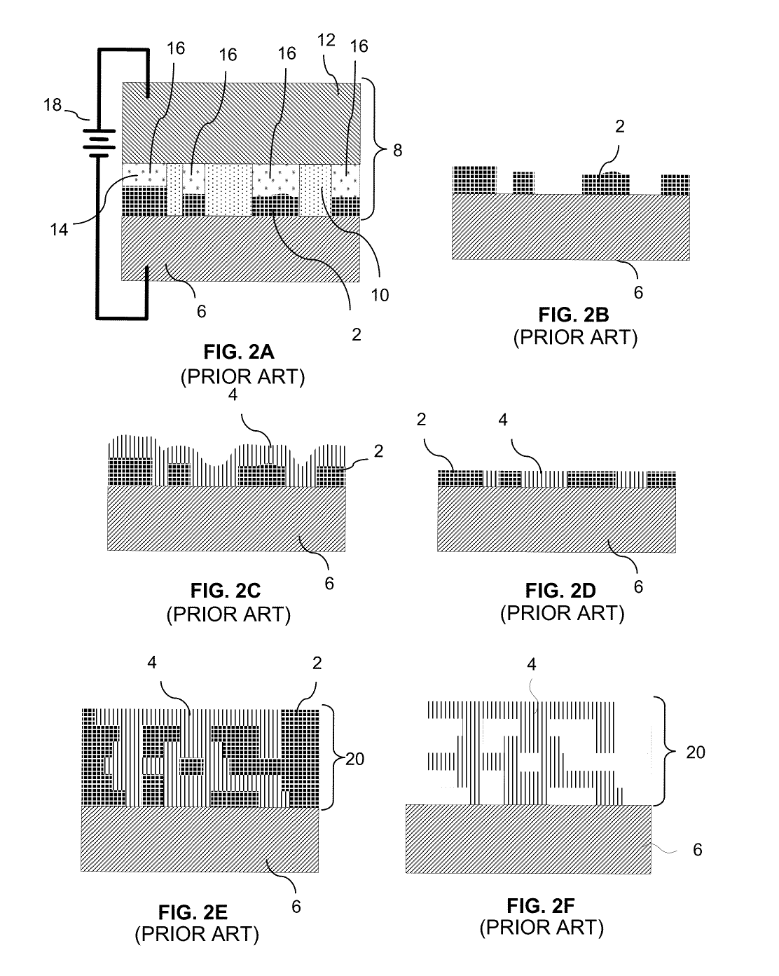

FIGS. 1A-1G, 2A-2F, and 3A-3C illustrate various features of one form of electrochemical fabrication. Other electrochemical fabrication techniques are set forth in the '630 patent referenced above, in the various previously incorporated publications, in various other patents and patent applications incorporated herein by reference. Still others may be derived from combinations of various approaches described in these publications, patents, and applications, or are otherwise known or ascertainable by those of skill in the art from the teachings set forth herein. All of these techniques may be combined with those of the various embodiments of various aspects of the invention to yield enhanced embodiments. Still other embodiments may be derived from combinations of the various embodiments explicitly set forth herein.

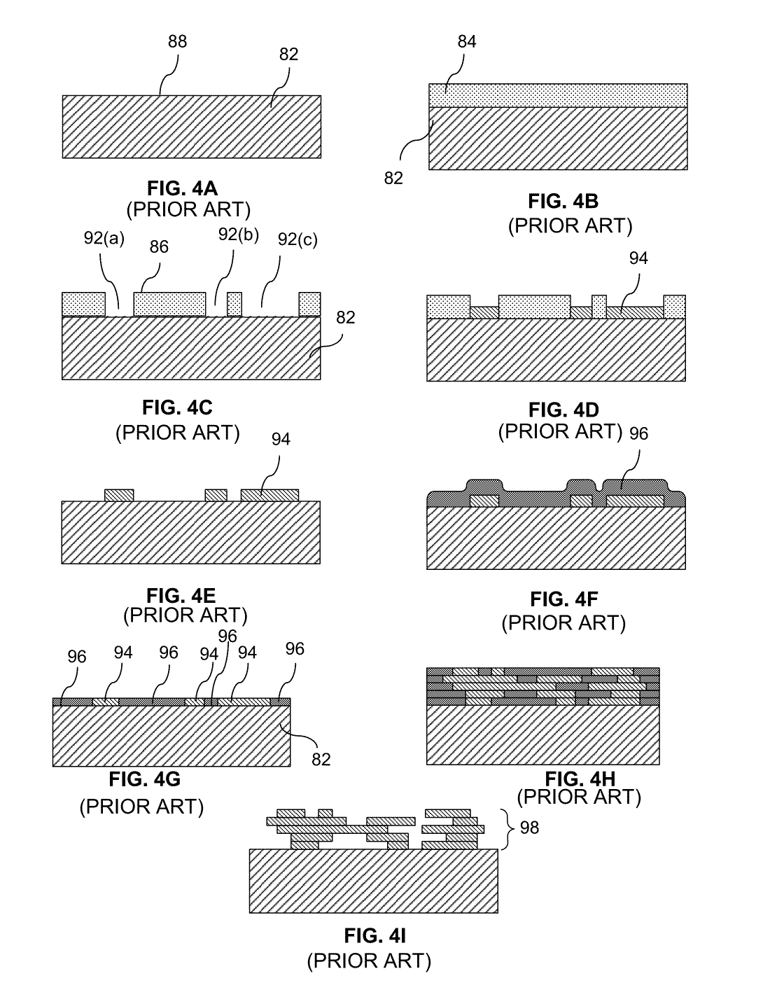

FIGS. 4A-4I illustrate various stages in the formation of a single layer of a multi-layer fabrication process where a second metal is deposited on a first metal as well as in openings in the first metal so that the first and second metal form part of the layer. In FIG. 4A a side view of a substrate 82 is shown, onto which patternable photoresist 84 is cast as shown in FIG. 4B. In FIG. 4C, a pattern of resist is shown that results from the curing, exposing, and developing of the resist. The patterning of the photoresist 84 results in openings or apertures 92(a)-92(c) extending from a surface 86 of the photoresist through the thickness of the photoresist to surface 88 of the substrate 82. In FIG. 4D a metal 94 (e.g. nickel) is shown as having been electroplated into the openings 92(a)-92(c). In FIG. 4E the photoresist has been removed (i.e. chemically stripped) from the substrate to expose regions of the substrate 82 which are not covered with the first metal 94. In FIG. 4F a second metal 96 (e.g. silver) is shown as having been blanket electroplated over the entire exposed portions of the substrate 82 (which is conductive) and over the first metal 94 (which is also conductive). FIG. 4G depicts the completed first layer of the structure which has resulted from the planarization of the first and second metals down to a height that exposes the first metal and sets a thickness for the first layer. In FIG. 4H the result of repeating the process steps shown in FIGS. 4B-4G several times to form a multi-layer structure are shown where each layer consists of two materials. For most applications, one of these materials is removed as shown in FIG. 4I to yield a desired 3-D structure 98 (e.g. component or device).

The various embodiments, alternatives, and techniques disclosed herein may be used in combination with electrochemical fabrication techniques that use different types of patterning masks and masking techniques. For example, conformable contact masks and masking operations may be used, proximity masks and masking operations (i.e. operations that use masks that at least partially selectively shield a substrate by their proximity to the substrate even if contact is not made) may be used, non-conformable masks and masking operations (i.e. masks and operations based on masks whose contact surfaces are not significantly conformable) may be used, and adhered masks and masking operations (masks and operations that use masks that are adhered to a substrate onto which selective deposition or etching is to occur as opposed to only being contacted to it). Adhered mask may be formed in a number of ways including (1) by application of a photoresist, selective exposure of the photoresist, and then development of the photoresist, (2) selective transfer of pre-patterned masking material, and/or (3) direct formation of masks from computer controlled depositions of material.

Patterning operations may be used in selectively depositing material and/or may be used in the selective etching of material. Selectively etched regions may be selectively filled in or filled in via blanket deposition, or the like, with a different desired material. In some embodiments, the layer-by-layer build up may involve the simultaneous formation of portions of multiple layers. In some embodiments, depositions made in association with some layer levels may result in depositions to regions associated with other layer levels. Such use of selective etching and interlaced material deposited in association with multiple layers is described in U.S. patent application Ser. No. 10/434,519, by Smalley, and entitled “Methods of and Apparatus for Electrochemically Fabricating Structures Via Interlaced Layers or Via Selective Etching and Filling of Voids layer elements” which is hereby incorporated herein by reference as if set forth in full.

The “build axis” or “build orientation” is the axis or orientation that is perpendicular to the planes of the layers that are used in building up structures. The build axis points in the direction of layer build up.

An “up-facing feature” is an element dictated by the cross-sectional data for a given layer “n” and a next layer “n+1” that is to be formed from a given material that exists on the layer “n” but does not exist on the immediately succeeding layer “n+1”. For convenience the term “up-facing feature” will apply to such features regardless of whether the layers are stacked one above the other, one below the other, or along any other orientation of the build axis.

A “down-facing feature” is an element dictated by the cross-sectional data for a given layer “n” and a preceding layer “n−1” that is to be formed from a given material that exists on layer “n” but does not exist on the immediately preceding layer “n−1”. As with up-facing features, the term “down-facing feature” shall apply to such features regardless of whether the layers are stacked one above the other, one below the other, or along any other oriented build axis.

A “continuing region” is the portion of a given layer “n” that is dictated by the cross-sectional data for a given layer “n”, a next layer “n+1” and a preceding layer “n−1” that is neither up-facing nor down-facing for that layer “n”.

Various embodiments of various aspects of the invention are directed to formation of three-dimensional structures from materials some of which are to be electrodeposited. Some of these structures may be formed form a single layer of one or more deposited materials while others are formed from a plurality of layers of deposited materials (e.g. two or more layers, more preferably five or more layers, and most preferably ten or more layers). In some embodiments structures having features positioned with micron level precision and minimum features size on the order of tens of microns are to be formed. In other embodiments structures with less precise feature placement and/or larger minimum features may be formed. In still other embodiments, higher precision and smaller minimum feature sizes may be desirable.

In EFAB, with some exceptions, one normally thinks of using thicknesses of materials that are defined by the layer levels. In turn, layer levels, or layer thicknesses, are typically defined as the thickness between planarization operations that provide the boundaries between successive layers or the nominal boundaries between layer levels when interlacing techniques are used in forming structures. In some embodiments, the planarization operations may be successive planarization operations, as only one planarization operation occurs during the formation of each layer, while in other embodiments they are not. In some embodiments, multiple planarization operations may be performed during the formation of each layer or no planarization operations may be used during the formation of some layers. In such cases the determination of layer thickness may be more complicated. For example, layer levels may be extracted from the sampling resolution at which layer representation information is extracted from a three-dimensional CAD design. In a given build, regions of a structural conductive material are thought of in terms of integral multiples (i.e. n=1, 2, 3, . . . ) of a layer thickness, regions of sacrificial material are thought of in terms of integral multiples of layer thickness, and regions of dielectric are also thought of in terms of integral multiples of layer thickness.

Exceptions to this rule include seed layer and adhesion layer materials which are typically applied in thicknesses equal to small fractions of a layer thickness. Such coatings may be applied in a planar manner (e.g. over previously planarized layers of material) as taught in U.S. patent application Ser. No. 10/607,931. In other embodiments, such coatings may be applied in a non-planar manner, for example, in openings in and over a patterned masking material that has been applied to previously planarized layers of material as taught in U.S. patent application Ser. No. 10/841,383.

Another exception includes the layer-by-layer formation of thin metallic coatings (e.g. gold coatings) over portions of structural material. This last exception results in coating material forming cup-like shapes around the bottom & sides of regions that will receive deposits of structural conductive material and is similar in some respects to the resulting seed layer deposits that surround conductive structural material during some implementations of the non-planar seed layer approach. Examples of such techniques are set forth in U.S. Patent Application No. 60/533,897 and in U.S. patent application Ser. No. 11/029,221. These referenced patent applications also set forth a process for fully encapsulating the conductive structural material with other material. These referenced applications are incorporated herein by reference as if set forth in full herein.

Embodiments of the present innovation remove the previous mind set involving the need for dielectric coatings to be thick and particularly needing to be thick to achieve complete electric isolation of EFAB produced conductive structures. According to various embodiments of the present innovation thin coatings of dielectric material may be used to achieve electric isolation of conductive structures. Some potential advantages of using thin dielectric coatings include:
(1) Ability to effectively use sputtered materials in obtaining dielectric coatings capable of providing electrical isolation in EFAB™ processes;
(2) Ability to use dielectric coating processes for which it is difficult to obtain coatings as thick as typical EFAB™ layer thicknesses;
(3) Improved selection of dielectric materials—e.g. having improved dielectric properties or thermal properties (e.g. CTE) and the like;
(4) Reduction of stress in formed structures—thin dielectric coatings allow use of a bulkier filler material having a CTE closer to that of a first conductive material (the filler material may or may not be conductive);
(5) Allows use of enhanced geometries of dielectric and conductive materials—e.g. regions of dielectric material within single layers may be formed within filler material regions to improve overall dielectric properties, reduce eddy current effects within conductive filler material, and the like; and
(6) Allows formation of structures (e.g. electromagnetic coils) having finer detail, tighter coil windings and the like.

Embodiments of the invention may take a variety of forms some of which are set forth below in detail while others are described or summarized in a more cursory manner, while still others though not explicitly set forth will be apparent to those of skill in the art upon review of the teachings herein.

FIG. 5 provides a side sectional view an example structure 202 which may be formed using a conductive material 204 and dielectric material 206. The structure is built up on a layer-by-layer basis on a substrate 210 and in this example includes five layers. The structure may be formed, for example, using various techniques set forth in U.S. patent application Ser. No. 10/841,383 which was referenced above and which was filed in the name of Lockard et al. on May 26, 2004, and which is entitled “Methods for Electrochemically Fabricating Structures Using Adhered Masks, Incorporating Dielectric Sheets, and/or Seed Layers that are Partially Removed Via Planarization”.

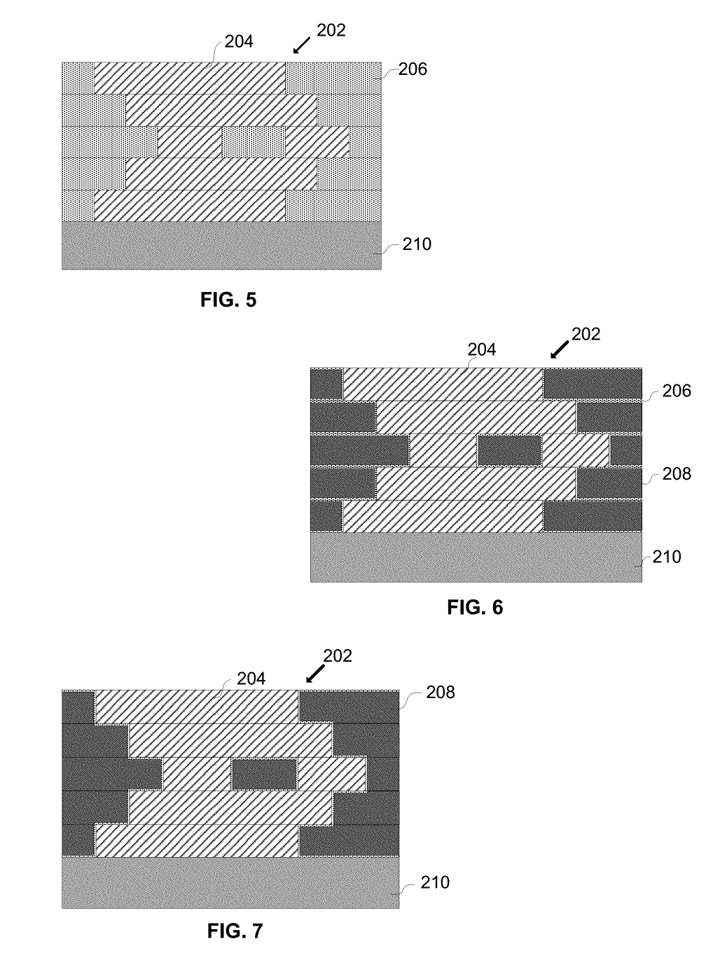

FIG. 6 provides a side view of a section of the same structure 202 of FIG. 5 and how it may look after being formed according to an embodiment of the present invention where thin coatings of dielectric material 206 are provided in a way that encapsulates and electrically isolates conductive structural material 204 from a filler material 208. The filler material 208 allows use of the thin dielectric by occupying space that would otherwise need to be filled by the dielectric. In some embodiments the filler material may be conductive while in other embodiments it may not be conductive (e.g. a dielectric with properties different from those of material 206). As can be seen in this example, each layer of filler material is fully encapsulated by dielectric material except for the ends of the layers. In some embodiments, the ends may never have received a dielectric material while in others a dielectric may have been applied and then removed (e.g. by dicing the structure from a larger build).

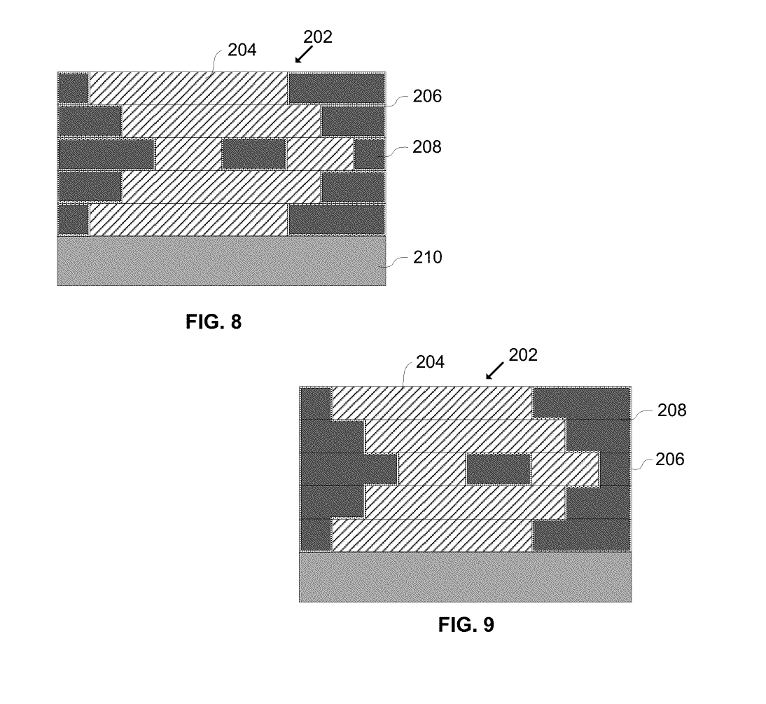

In variations of the embodiment exemplified by FIG. 6, the filler material 208 may be identical to or different from the conductive structural material 202. In other variations the ends of the layers may be capped with a dielectric as shown in FIG. 8. This capping may occur during the layer-by-layer build up and may remain after any dicing operation or it may occur during a post layer formation process, such as (1) via a sputtering process which is performed in a blanket or selective manner or (2) via a dielectric (e.g. epoxy or polyimide) over coating process (e.g. globbing, spraying spreading, spinning, or the like) where any excess material may be removed from the top surface and/or side surfaces via machining operations or the like. In some embodiments, the material which caps the ends of the layers may be different from the dielectric material that isolates the other portions of the layers.

In still other variations of the embodiment of FIG. 6, instead of considering the filler to be located in positions where dielectric material would otherwise be located, it may be more appropriate to consider all or portions of the filler material as part of the desired structure which is intended to be electrically separated from the regions occupied by material 204. In still other variations, the thin dielectric coating may be considered a necessary part of the structure and it should be understood that regions previously noted as “filler regions” (within a single layer) may be divided into pockets of filler separated by thin horizontal barriers of dielectric or divided by vertically extending barriers of dielectric material as necessary to give desired electrical or other properties. In still further variations, the structure may be formed with more than three materials (204, 206, and 208). In such embodiments, one or more of the materials may be sacrificial materials that will be removed at an appropriate time to yield a structure not only with desired electric or other properties within a block but also a structure having a desired, externally accessible structural configuration.

FIG. 7 provides a side view of a section of the same structure 202 of FIGS. 5, 6, and 8 and how it may look after being formed according to another embodiment of the present invention where thin coatings or barriers of dielectric material 206 are provided only where necessary to isolate material 206 from material 204. In some embodiments it may be desirable to isolate material 206 from the substrate as well In other embodiments, it may be desirable to leave the regions occupied by material 206 in electrical contact with the substrate (e.g. when the substrate is a dielectric with conductive paths located at selective locations and the filler material is conductive and it is desired to hold the filler material at a preset potential). In still other alternative embodiments it may be possible to make electrical contact to the filler 206 and/or conductive structural material 202 in other ways (e.g. wire bonding, solder bump connections, or the like). FIG. 9 provides an example structure similar to that of FIG. 7 with the exception that the ends of the layers are coated with dielectric 206.

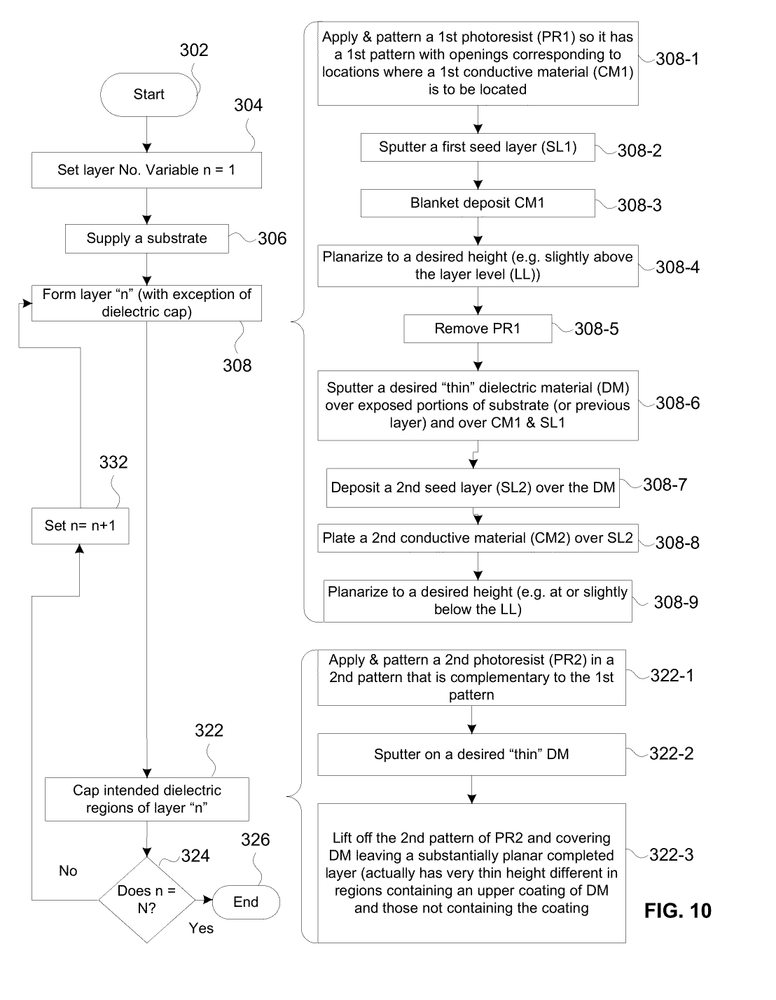

FIG. 10 provides a flowchart of an embodiment of the invention which allows the formation of metal structures using thin coatings of dielectric material (e.g. sputtered dielectrics) where the top coating of dielectric material for a given layer is obtained from a patterned photoresist which is temporarily located on top of an otherwise completed and planarized layer. The process of FIG. 10 may be used to approximate the formation of the structure of FIG. 6.

The process of FIG. 10 begins with the “start” block 302 and then moves forward to block 304 which calls for setting a layer number variable, n, to one (n=1). The process then moves forward to block 306 which calls for providing a substrate on which a plurality of layers may be formed. Block 308 comes next and calls for the formation of an nth layer (i.e. layer “n”) but without any dielectric capping material on its upper surface (i.e. the surface which is not bonded to the previously formed layer or substrate but instead faces away from it regardless of the actual build orientation used in forming the structure). The operation of block 308 is implemented via a plurality of operations indicated by blocks 308-1 to 308-9 which will be discussed herein shortly. After formation of layer “n” the process moves forward to block 322 which calls for capping layer “n”, i.e. capping the portions of layer “n” not occupied by the first conductive material (CM1) or the first seed layer (SL1). In this embodiment, the capping operation is performed via a plurality of operations indicated by blocks 322-1 to 322-3. After the layer is capped, the process moves forward to decision block 324 where an inquiry is made as to whether layer variable “n” is equal to “N” (i.e. the number of the last layer to be formed). If the response to the inquiry is “yes” the process moves to block 326 where it ends. If the response is “no”, the process moves to block 332 where “n” is incremented by one, and then the process loops back to operation 308 to form the next layer. The process then repeats until all layers are formed and capped.

The operations used in forming the layer (according to block 308) in this embodiment include (1) applying and patterning a masking material (e.g. a first photoresist—PR1) to leave openings where a first conductive material (CM1) is to be located—block 308-1, (2) applying a first seed layer (SL1)—block 308-2, (3) depositing CM1 to a height which extends above the upper level of the layer being formed—block 308-3, (4) planarizing CM1, PR1, and SL1 to set the height of the partially formed layer to a level at or slightly above the layer's intended upper level—block 308-4, (5) removing the masking material (e.g., striping PR1)—block 308-5, (6) applying a thin layer of dielectric material (DM)—block 308-6, (7) applying a second seed layer (SL2)—block 308-7, (8) depositing a second conductive material (i.e. the filler material—CM2)—block 308-8, and (9) planarizing the materials to a level that corresponds to an upper level of the layer or possibly slightly less than the upper level of the layer depending on whether or not the capped layer will have an upper surface corresponding to the layer level or whether the pre-capped layer will have its upper surface at the level of the upper surface of the layer—block 308-9.

The operations used in capping the layer (according to block 322) in this embodiment include (1) applying and patterning a masking material (e.g. a second photoresist—PR2) to have one or more openings over regions of layer “n” where CM1 or SL1 were not deposited—e.g. the pattern is the complement of the pattern of PR1—block 322-1, (2) applying a thin layer of DM, e.g. by sputtering—block 322-2, (3) lifting off PR2 and any covering DM to yield the capped final layer “n” which is substantially planar—block 322-3.

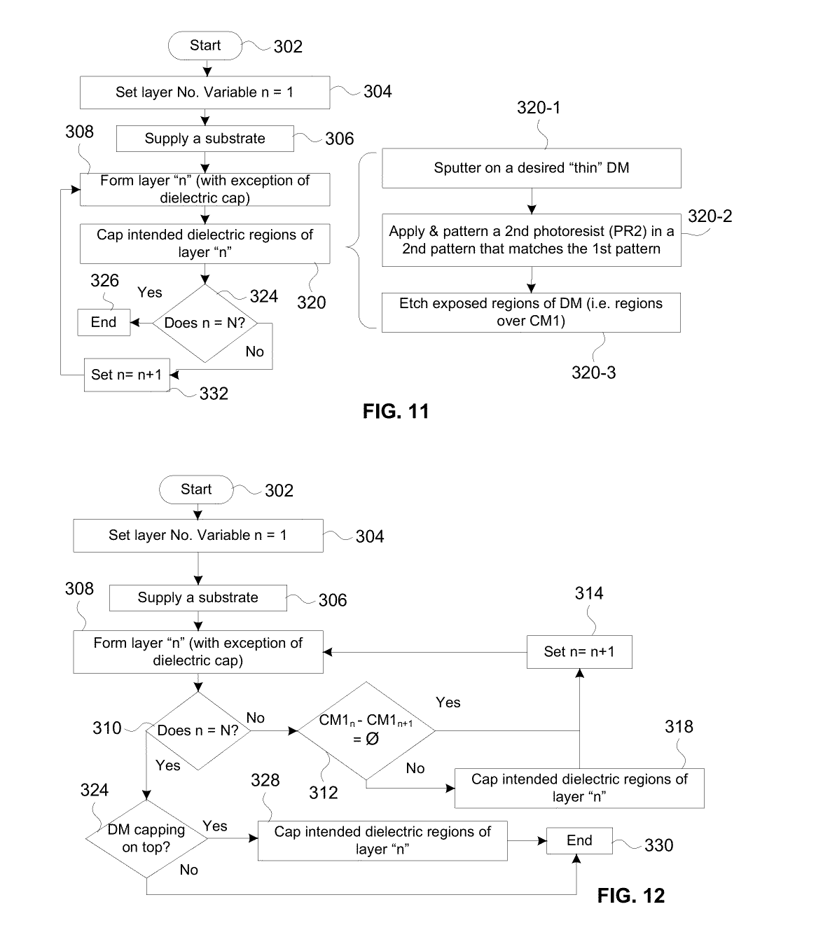

FIG. 11 provides a flowchart of another embodiment of the invention which allows the formation of metal structures using thin coatings of dielectric material (e.g. sputtered dielectrics) where the top coating of dielectric material for a given layer is obtained from blanket deposited dielectric material over which a masking material is applied and patterned and then undesired portions of the dielectric material removed.

The process of FIG. 11 is similar to that of FIG.6 with the exception that operation 322, the capping operation, and associated operations 322-1 to 322-2 are replaced by a different capping operation 320 and associated operations 320-1 to 320-3. The operations used in capping the layer (according to block 320) in this embodiment include (1) applying a thin layer of DM, e.g. by sputtering—block 320-1, (2) applying and patterning a masking material (e.g. a second photoresist—PR2) to have one or more openings over regions of layer “n” where CM2 and DM were deposited—i.e. the pattern is the same as the pattern of PR1—block 320-2, (3) etching the DM to remove undesired, i.e. exposed, portions and then removing PR2 which results in completion of the formation of the layer—block 320-3.

Many alternatives to the embodiments of FIGS. 10 and 11 are possible. For example, instead of starting layer formation with deposition of CM1, layer formation may start with the (1) selective deposition of the DM, followed by (2) deposition of SL2, (3) deposition of CM2, (4) planarization, (5) removal of masking material used in allowing the selective depositions, (6) deposition of SL1, (7) deposition of CM1, and finally (8) planarization. In other alternatives, additional operations may be added to allow a third material to be deposited to selected regions (e.g. via a selective etching operation into the one or both of the deposited materials, followed by deposition of a seed layer, if needed, and then deposition of the third material, and then another planarization operation—if needed. In still other embodiments, it may be possible to eliminate the need for seed layer applications by using electroless deposition operations to deposit, for example, CM1 and CM2. In still other embodiments, the CM2 may be replaced by a second dielectric material, DM2, in which case the application of the second seed layer, SL2, may be eliminated.

FIG. 12 provides a flowchart of another embodiment of the invention which allows the formation of metal structures using thin coatings of dielectric material (e.g. sputtered dielectrics) where the top coating of dielectric material for a given layer is applied only when the top of a given material on layer “n” won't be automatically and appropriately covered in its entirety by formation of the next layer. In the embodiment of FIG. 12 the layer may be formed in a variety of manners (e.g. similar to the process associated with FIG. 10 and its alternatives) and the capping of the dielectric regions may occur in a variety of manners (e.g. similar to the processes associated with FIGS. 10 and 11 and their alternatives). The uniqueness of this embodiment involves the use of Boolean operations to determine when capping operations are necessary and then only implementing such operations on those layers when they are required.

The process of the embodiment of FIG. 12 begins with block 302 and the then moves forward to block 304 which calls for setting a layer number variable, n, to one (n=1). The process then moves forward to block 306 which calls for the providing of a substrate on which layers may be formed. Next the process moves forward to block 308 which calls for the formation of layer “n” exclusive of any dielectric capping material.

After formation of layer “n” the process moves to decision block 310 which inquires as to whether the layer number variable “n” equals the number of the final layer to be formed “N”. If the inquiry produces a positive response, the process moves forward to block 324 which is another decision block which inquires as to whether the last layer should receive a cap of dielectric material. If the response to the inquiry of block 310 is negative, the process moves forward to block 312.

If the response to the inquiry of block 324 is negative, the process moves forward to block 330 and the process ends. After the end of the process additional operations may be performed to complete the fabrication and to prepare the produced structure/device or structures/devices for shipment or use. If the response to the inquiry of block 324 is positive, the process moves forward to block 328 which calls for the capping of the last layer with a dielectric. The operations of block 328 may be a selective or blanket capping operation depending on the desired result and the operations used. From operation 328 the process moves forward to block 330 and ends.

As noted above, a negative response to the inquiry of block 310 causes the process to move forward to block 312 which is another decision block. Block 312 inquires as to whether the Boolean difference (i.e. Boolean subtraction) between the area of the first conductive material on layer “n” (CM1ₙ)and the area of first conductive material on layer “n+1” (CM1ₙ₊₁) is null:

CM1ₙ−CM1ₙ₊₁=null?

FIGS. 14A-14D provide examples of Boolean differencing (i.e. Boolean subtraction) operations as applied to a first region identified with hatching in FIG. 14A and a second region identified with hatching in FIG.14B. As can be seen in this example, the two areas overlap. FIG. 14C provides the result of a subtracting the second region from the first region (i.e. the area of the first region minus the area of the second region) where the result is the portion of the first region that is not overlaid (i.e. is not intersected) by any of the second region. FIG. 14D provides the result of the opposite differencing operation (i.e. the area of the second region minus the area of the first region) where the result is the portion of the second region that is not overlaid by any of the first region.

If the inquiry of block 312 produces a positive response, there is no need to cap layer “n” with a dielectric as it will be appropriately covered during the formation of layer “n+1”. A positive response causes the process to move forward to block 314 which increments the layer number “n” by one and thereafter the process loops back to block 308 for formation of the next layer. If the inquiry of block 312 produces a negative response, the process moves forward to block 318 which calls for the capping of appropriate portions of CM1 on layer “n” with a dielectric before moving on to the formation of layer “n+1”. After completion of the capping, the process moves to block 314 (as discussed above) which calls for the incrementing of the layer variable by one and then the process loops back to block 308 for formation of the next layer. The process then continues through the various operations and loops until the entire structure or structures are formed.

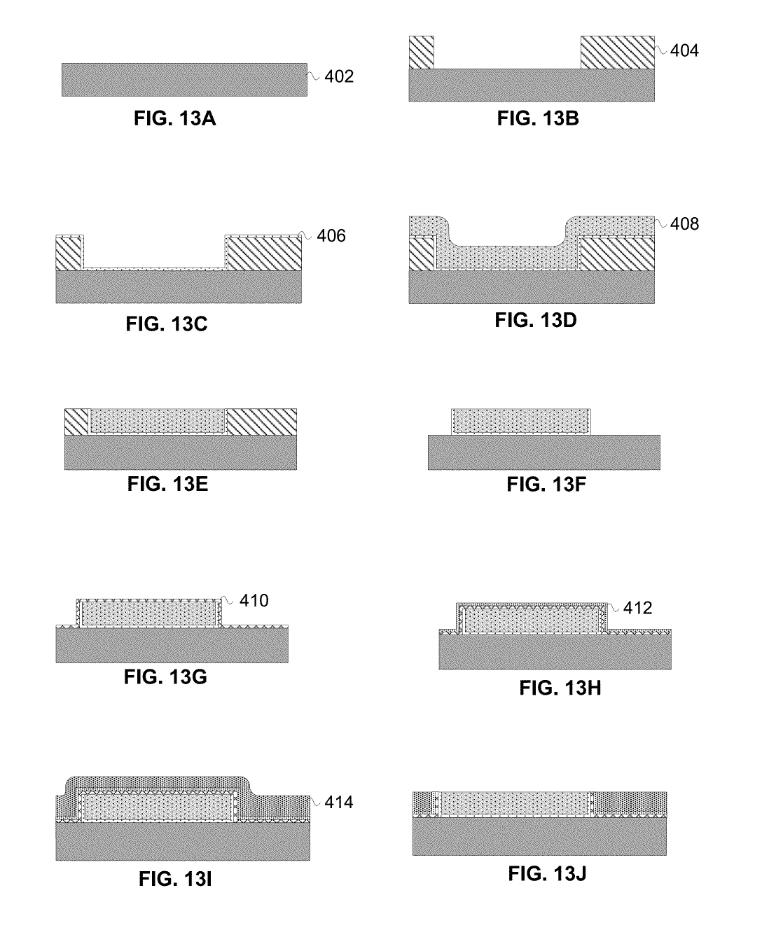

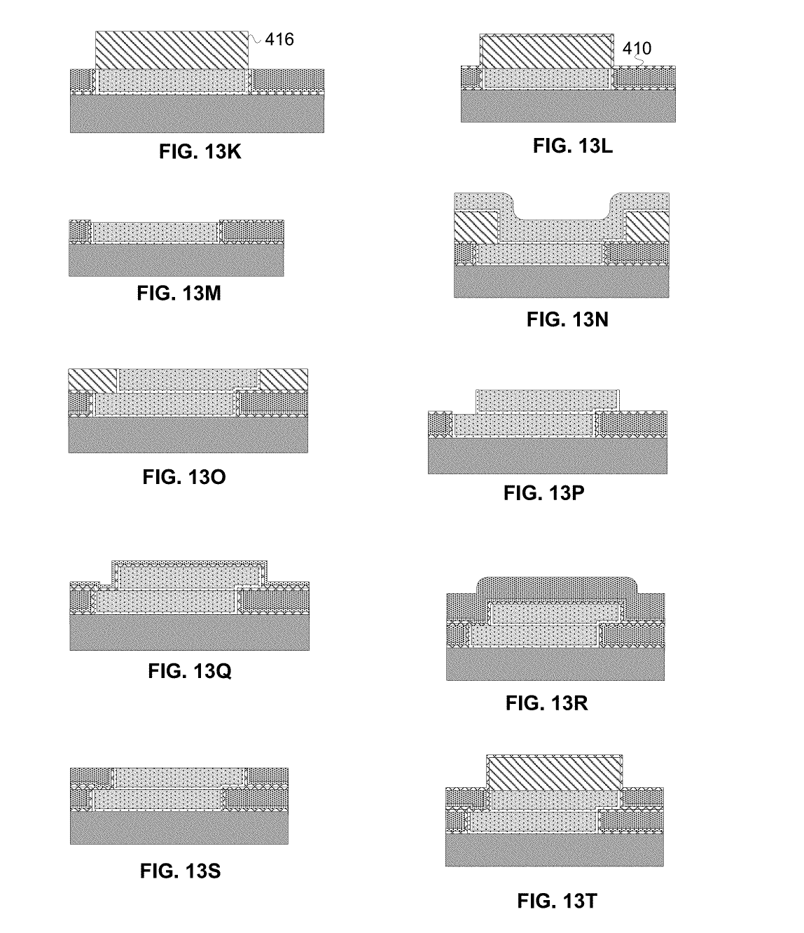

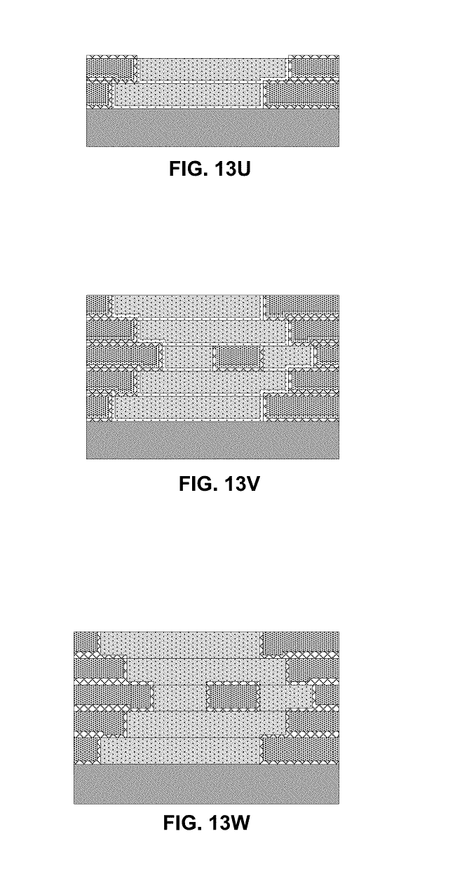

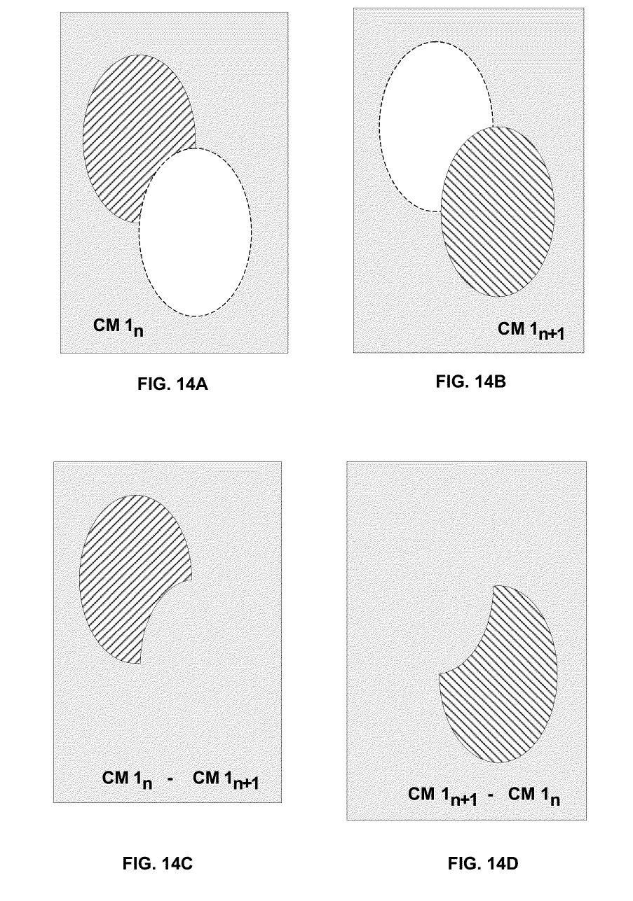

FIG. 13A-13W illustrate the operations of the process of FIG. 10 as applied to formation of the structure of FIG. 5 while the resulting structure is shown in FIG. 13W. It can be seen that the structure resulting from the application of the process of FIG. 10 does approximate the formation of the structure shown in FIG. 6.

FIG. 13A depicts a substrate 402 on which a desired structure may be formed. Substrate 402 may be a permanent substrate or a temporary substrate. If it is a temporary substrate, it may be formed of a sacrificial material or it may include a layer of a sacrificial material, or alternatively it may be releasable from the formed structure via a different mechanism (e.g. it may be flexible and be capable of being peeled from the structure).

FIG. 13B depicts the first operation involved in forming the first layer of the structure. FIG. 13B depicts the state of the process after the operation of block 308-1 of FIG. 10 applies and patterns a masking material 404 (e.g. a first photoresist—PR1) to have openings where a first conductive material (CM1) 408 is to be deposited.

FIG. 13C depicts the state of the process after the operation of block 308-2 has applied a first seed layer 406 (SL1) to the masking material and to the exposed portions of the substrate.

FIG. 13D depicts the state of the process after the operation of block 308-3 deposits the first conductive material 408, CM1.

FIG. 13E depicts the state of the process after the operation of block 308-4 planarizes CM1, PR1, and the vertical extending portions of SL1.

FIG. 13F depicts the state of the process after the operation of block 308-5 removes the first photoresist 404, PR1.

FIG. 13G depicts the state of the process after the operation of block 308-6 applies a thin coating of dielectric material 410, DM.

FIG. 13H depicts the state of the process after the operation of block 308-7 applies a second seed layer 412, SL2.

FIG. 13I depicts the state of the process after the operation of block 308-8 deposits a filler material 414 (e.g. a second conductive material, CM2).

FIG. 13J depicts the state of the process after the operation of block 308-9 planarizes CM1, SL1, DM, SL2, and CM2 at a level which corresponds to the upper level of the layer.

FIG. 13K depicts the state of the process after the operation of block 322-1 applies and patterns a masking material 416 (e.g. a second photoresist—PR2) to have openings where capping dielectric material is to be deposited.

FIG. 13L depicts the state of the process after operation 322-2 applies a thin coating of dielectric material 410 to cap desired portions of the first layer.

FIG. 13M depicts the state of the process after operation 322-3 removes the second photoresist and the overlying dielectric material to complete formation of the layer including its dielectric cap.

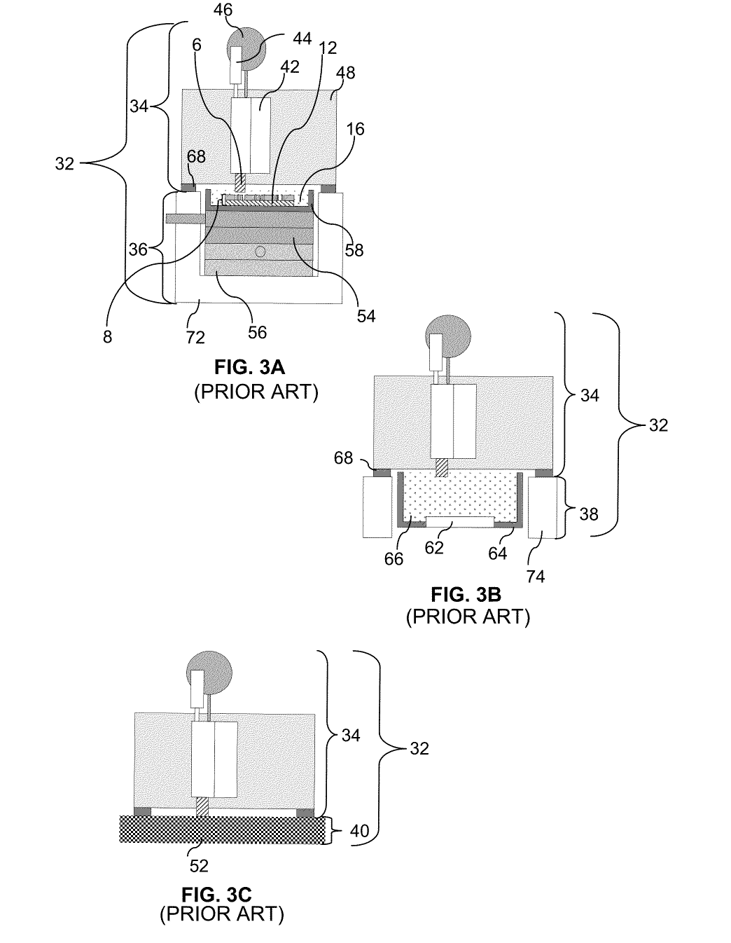

FIG. 13N shows the state of the process after the operations yielding FIGS. 13B-3D are repeated during formation of the second layer.

FIGS. 13O and 13P show the state of the process after the operations yielding FIGS. 13E and 13F are repeated during formation of the second layer.

FIG. 13Q shows the state of the process after the operations yielding FIGS. 13G and 13H are repeated during formation of the second layer.

FIGS. 13R and 13S show the state of the process after the operations yielding FIGS. 13I and 13J are repeated during formation of the second layer.

FIG. 13T shows the state of the process after the operations yielding FIGS. 13K and 13L are repeated during formation of the second layer.

FIG. 13U shows the state of the process after the operation yielding FIG. 13K is repeated during formation of the second layer.

FIG. 13V depicts the state of the process after repeating operations of blocks 308-1 to 308-9 and 322-1 to 322-3 for the formation layers 3 and 4 and repeating operations 308-1 to 308-9 for the formation of layer 5. FIG. 13W depicts the same state of the process as shown in FIG. 13V with the exception that SL1 is merged with CM1 on individual layers, SL2 is merged with CM2 on individual layers, and DM material on individual layers is shown as merged. In furtherance of this embodiment, operations 322-1 to 322-3 could be applied to layer 5 in order to provide dielectric capping if desired. In still other alternatives, further steps may be taken to cap the sides of the layers with dielectric material.

The embodiment of the example of FIG. 7 may be implemented or approximated via a variety of processes. As an example of such a process, the following operations may be used in implementing the embodiment.
1. Receive data representing a structure to be formed from a first and second material where regions to deposit thin dielectric material are not specifically identified but whose locations will be determined as boundary regions between the first and second materials. In this embodiment it is assumed that the second material (i.e. the second of the two materials to be deposited) will be the one which is to be surrounded by dielectric.
2. Process the data to identify up-facing, down-facing, continuing regions and regions which are both up-facing and down-facing for the second material. In this embodiment, it is intended that down-facing regions will be bounded from below by dielectric material, up-facing regions will be bounded from above by dielectric material and sidewalls of each of the various regions will be bounded by dielectric material.
3. During the formation of a layer “n”, determine if layer “n−1” included any up-facing material regions for the second material. If so, mask the upper surface of layer “n−1”, leaving one or more openings for depositing a thin layer of dielectric to the up-facing region or regions and then deposit the dielectric. The dielectric may be supplied in directional manner (e.g. parallel to the build axis) or in a non-directional manner. If necessary the upper surface of the dielectric coated masking material may be scratched or planarized and then the mask and overlying dielectric removed leaving behind a coating of dielectric over the up-facing surface of the second material on layer “n−1”. If layer “n−1” did not include an up-facing surface skip these operations.
4. Determine if a seed layer is necessary, for depositing the 1^{st} material onto layer “n−1”. In some variations of this embodiment, a seed layer may always be formed while in other variations the determination may involve determining whether any up-facing region or regions existed on layer “n−1” that have a width or pattern that would inhibit the deposition of the first material. The determination may involve consideration of how the first material will be deposited on layer “n”, whether or not conductivity of the existing surface is necessary for successful deposition (e.g. will the first material be deposited by electroplating, electroless plating, or via some other technique), whether mushrooming of electroplated material can readily bridge any dielectric regions.
5. Mask the surface of layer “n−1” leaving openings for receiving the first material, deposit a seed layer if desired, deposit the first material, and scratch or planarize the deposited materials (e.g. at level above the upper level of layer “n”) to remove the seed layer and then remove the masking material.
6. Deposit a thin layer of dielectric onto the surface of the first deposited material, on to the sidewalls of the first deposited material (or seed layer if present) and onto exposed portions of layer “n−1”.
7. Determine whether any down-facing regions for the second material exist on layer “n”. If one or more down-facing regions exist on layer n, apply a masking material to the dielectric material and pattern the masking material to create openings in all non-down-facing regions. If no down-facing regions exist, skip the masking and patterning operations.
8. Perform a directional etch of the deposited dielectric material. Assuming that layer build up is occurring along the z-axis, the directional etching should operate along the z-axis removing the thin coating of dielectric material in that direction and leaving most of the tall but narrow coating of dielectric material along the side walls of the first material and leaving the dielectric material that is protected by the masking material.
9. Remove the masking material (if it was applied in 6.).
10. Deposit the second material. If the second material is being electrodeposited (e.g. electroplated) and if large down-facing regions exist or if they create a pattern that would make it difficult to deposit the second material, a seed layer (e.g. an adhesion layer and a plating base) may be applied prior to depositing the second material. If no down-facing regions exist, or if the second material is going to be deposited in an electroless manner or in some other manner that does not require a conductive base, it may be possible to eliminate the seed layer formation operations.
11. Planarize the deposited materials to complete formation of layer “n” with the possible exception of any dielectric cap that is necessary.
12. Repeat 3-11 to form additional layers.
13. If layer “n” is the last layer and if a dielectric cap is necessary, mask formation may occur, followed by dielectric deposition (directional or non-directional), followed by mask removal may occur to complete formation of the structure or device.

Other alternative implementations are possible. For example, the material that is to be encased in dielectric may be the first deposited material and various modifications to the above outlined process may be made. In still other embodiments, more than two materials may be used and the material to be encased in dielectric may be any one of the materials. In still other embodiments, for the purpose of determining where dielectric material should be deposited, multiple materials may be treated as a single material for determining the various up-facing regions, down-facing regions, and the like. In still other embodiments, other Boolean operations may be performed to determine the regions of each layer that will receive dielectric material. The regions may be determined via programmed algorithms or via manual selection or via a combination.

In still other embodiments, the determinations of alternative actions may be completed entirely up front (prior to beginning formation of the structure) or they may be determined on an as needed basis during formation of the structure.

In still other embodiments, the directional etching operations may be eliminated in favor of additional masking operations and potential approximations concerning the widths of some dielectric placement. If masking operations will be solely used to set dielectric placement, it may be necessary to create some regions of dielectric that would otherwise not be desirable in order to meet any minimum width requirements associated with forming viable masks or openings in masks or associated with maximum (height to width) aspect ratios for openings into which dielectric material may be reliably deposited. Widths of various regions on each layer may be determined by various processes including, for example, via erosion or expansion routines as set forth in U.S. patent application Ser. No. 10/434,519; and in U.S. Pat. Nos. 5,945,058; 5,999,184; 6,103,176; and 6,024,980 which are incorporated herein by reference as if set forth in full herein. These incorporated applications also provide further teachings on the use of Boolean operations in manipulating data that may be useful in alternative implementations of some embodiments of the present invention. Based on the results of width determinations, minimum width requirements, and the like, the extent of the approximation and the impacted layers may be determined.

It will be understood by those of skill in the art that the other processes may be defined to achieve other desired results, such as for example, those illustrated in FIGS. 7, 8, and 9 or approximations thereof. Various additional alternatives to the present embodiments are possible and will be apparent to those of skill in the art upon review of the teachings herein. In particular various alternative embodiments may be derived from a combination of the present embodiment with other embodiments explicitly set forth herein. Still further embodiments will be understood by those of skill in the art based on a combination of the teachings explicitly set forth herein and the teachings incorporated herein by reference. Even further embodiments will be understood by those of skill in the art based on numerous alternative layer data representation schemes that can be developed.

It will be understood by those of skill in the art or will be readily ascertainable by them that various additional operations may be added to the processes set forth herein. For example, between performances of the various deposition operations, the various etching operations, and the various planarization operations cleaning operations, activation operations, and the like may be desirable.

Some embodiments may employ diffusion bonding or the like to enhance adhesion between successive layers of material. Various teachings concerning the use of diffusion bonding in electrochemical fabrication processes are set forth in U.S. patent application Ser. No. 10/841,384 which was filed May 7, 2004 by Cohen et al. which is entitled “Method of Electrochemically Fabricating Multilayer Structures Having Improved Interlayer Adhesion” and which is hereby incorporated herein by reference as if set forth in full. This application is hereby incorporated herein by reference as if set forth in full.

Further teachings about planarizing layers and setting layers thicknesses and the like are set forth in the following US Patent Applications which were filed Dec. 31, 2003: (1) U.S. Patent Application No. 60/534,159 by Cohen et al. and which is entitled “Electrochemical Fabrication Methods for Producing Multilayer Structures Including the use of Diamond Machining in the Planarization of Deposits of Material” and (2) U.S. Patent Application No. 60/534,183 by Cohen et al. and which is entitled “Method and Apparatus for Maintaining Parallelism of Layers and/or Achieving Desired Thicknesses of Layers During the Electrochemical Fabrication of Structures”. The techniques disclosed explicitly herein may benefit by combining them with the techniques disclosed in U.S. patent application Ser. No. 11/029,220, filed Jan. 3, 2005 by Frodis, et al., and which is entitled “Method and Apparatus for Maintaining Parallelism of Layers and/or Achieving Desired Thicknesses of Layers During the Electrochemical Fabrication of Structures”. These patent filings are each hereby incorporated herein by reference as if set forth in full herein.

Additional teachings concerning the formation of structures on dielectric substrates and/or the formation of structures that incorporate dielectric materials into the formation process and possibility into the final structures as formed are set forth in a number of patent applications: (1) U.S. Patent Application No. 60/534,184, by Cohen, which as filed on Dec. 31, 2003, and which is entitled “Electrochemical Fabrication Methods Incorporating Dielectric Materials and/or Using Dielectric Substrates”; (2) U.S. Patent Application No. 60/533,932, by Cohen, which was filed on Dec. 31, 2003, and which is entitled “Electrochemical Fabrication Methods Using Dielectric Substrates”; (3) U.S. Patent Application No. 60/534,157, by Lockard et al., which was filed on Dec. 31, 2004, and which is entitled “Electrochemical Fabrication Methods Incorporating Dielectric Materials”; (4) U.S. Patent Application No. 60/574,733, by Lockard et al., which was filed on May 26, 2004, and which is entitled “Methods for Electrochemically Fabricating Structures Using Adhered Masks, Incorporating Dielectric Sheets, and/or Seed Layers that are Partially Removed Via Planarization”; and U.S. Patent Application No. 60/533,895, by Lembrikov et al., which was filed on Dec. 31, 2003, and which is entitled “Electrochemical Fabrication Method for Producing Multi-layer Three-Dimensional Structures on a Porous Dielectric”. The techniques disclosed explicitly herein may benefit by combining them with the techniques disclosed in U.S. patent application Ser. No. 11/029,216 filed concurrently herewith by Cohen et al. and entitled “Electrochemical Fabrication Methods Incorporating Dielectric Materials and/or Using Dielectric Substrates”. These patent filings are each hereby incorporated herein by reference as if set forth in full herein.

Some embodiments may not use any blanket deposition process and/or they may not use a planarization process. Some embodiments may involve the selective deposition of a plurality of different materials on a single layer or on different layers. Some embodiments may use blanket or selective depositions processes that are not electrodeposition processes. Some embodiments may form structures from two or more materials where one or more of the materials are coated with thin deposits of dielectric material and one or more materials are treated as a sacrificial material and removed after the formation of a plurality of layers. Some embodiments may use nickel or a nickel alloy as a structural material while other embodiments may use different materials such as gold, silver, or any other electrodepositable materials. Some embodiments may use copper as the structural material with or without a sacrificial material. Some embodiments may remove a sacrificial material while other embodiments may not.

Many other alternative embodiments will be apparent to those of skill in the art upon review or the teachings herein. Further embodiments may be formed from a combination of the various teachings explicitly set forth in the body of this application. Even further embodiments may be formed by combining the teachings set forth explicitly herein with teachings set forth in the various applications and patents referenced herein, each of which is incorporated herein by reference.

Furthermore, U.S. Application Nos. 60/533,975, filed Dec. 31, 2003; 60/533,947, filed Dec. 31, 2003; and 60/533,948, filed Dec. 31, 2003; 60/540,510, filed Jan. 29, 2004; Ser. No. 10/949,738, filed Sep. 24, 2004; Ser. No. 10/772,943, filed Feb. 4, 2004; 60/445,186, filed Feb. 4, 2003; 60/506,015, filed Sep. 24, 2003; 60/533,933, filed Dec. 31, 2003, and 60/536,865 filed Jan. 15, 2004 are incorporated herein by reference.

In view of the teachings herein, many further embodiments, alternatives in design and uses of the instant invention will be apparent to those of skill in the art. As such, it is not intended that the invention be limited to the particular illustrative embodiments, alternatives, and uses described above but instead that it be solely limited by the claims presented hereafter.

1-19. (canceled)

20. A method of forming a three dimensional, multi-layer, metal structure having a thin outer barrier of a dielectric material located on sidewalls and any intervening up-facing and down-facing surfaces, wherein each of a plurality of layers is formed from a plurality of successively deposited and adhered multi-material layers, the method comprising:
(1) for each layer of the plurality of successively deposited and adhered multi-material layers:
(a) depositing a metal structural material to desired lateral portions of the layer and to a thickness exceeding a thickness of the layer;
(b) depositing a dielectric structural material to lateral portions of the layer that will locate the dielectric structural material directly or indirectly on the sidewalls of the metal structural material wherein a width of the dielectric material along the side walls forms a thin barrier and depositing thin barriers of dielectric structural material to at least one of (1) up-facing surfaces of the metal structural material that may exist on the layer with the possible exception of such up-facing surfaces that will exist on the last layer of the structure, or (2) to locations that will be overlaid by down-facing surfaces of the metal structural material of the layer with the possible exception of such down-facing surfaces that will exist on a first layer of the structure;
(c) depositing a sacrificial material;
(d) planarizing the deposited metal structural, the dielectric structural material and the sacrificial material to set a boundary level for the layer;
(2) repeating the operations of (1)(a) to (1)(d) a plurality of times to build up the multi-layer structure from the plurality of multi-material layers;
(3) after forming each of the plurality of layers, separating the sacrificial material from the metal structural material and the dielectric structural material on each layer to reveal the multi-layer three dimensional structure having a thin barrier of dielectric material,
wherein the thin barrier of dielectric material has a thickness less than the layer thickness as measured along a normal to a surface of the metal structural material that is being bounded by the dielectric material, and
wherein each successive layer of the plurality of layers represents a successive cross-section of the three-dimensional structure.

21. The method of claim 20 wherein the sacrificial material is a metal material and a first layer of the plurality of layers is formed on a substrate and wherein the structure is released from the substrate after formation.

22. The method of claim 20 wherein the sacrificial material is a metal material and a first layer of the plurality of layers is formed on a substrate and wherein the structure remains attached to the substrate when the structure is put into use.

23. The method of claim 20 wherein the thin barrier of dielectric structural material has a thickness selected from the group consisting of (a) less than 50% of the layer thickness, (b) less than 25% of the layer thickness, and (c) less than 10% of the layer thickness.

24. The method of claim 20 wherein the metal structural material is a different metal material on two different layers.

25. The method of claim 20 wherein the depositing of the metal structural material is selected from the group consisting of: (a) electroplating and (b) electroless plating.

26. The method of claim 20 wherein a seed layer material is deposited onto the dielectric material prior to deposition of the metal structural material.

27. The method of claim 26 wherein the seed layer material is selected from the group consisting of (1) a single seed layer material and (2) an adhesion layer and seed layer combination of materials.

28. The method of claim 20 additionally comprising converting a three-dimensional computer data representation of the structure into a plurality of two-dimensional layer representations, each having a layer thickness and performing a plurality of Boolean layer comparison operations.

29. The method of claim 20 wherein an order of performing the operations of element (1) is (a) then (b) then (c) then (d).

30. A method of forming a three dimensional, multi-layer, metal structure having at least two metal elements that are electrically isolated from one another by a thin barrier of a dielectric structural material, wherein each of a plurality of layers are formed from a plurality of successively deposited and adhered multi-material layers, the method comprising:
(1) for each layer of the plurality of successively deposited and adhered multi-material layers:
(a) depositing at least one metal structural material to desired lateral portions of the layer and to a thickness exceeding a thickness of the layer;
(b) depositing a sacrificial material;
(c) planarizing the deposited metal structural material and the sacrificial material to set a boundary level for the layer;
(2) repeating the operations of (1)(a) to (1)(c) a plurality of times to build up the at least two components of the multi-layer structure from the plurality of multi-material layers;
wherein formation of at least one of the plurality of successively deposited and adhered multi-material layers, additionally comprises depositing a dielectric structural material to form at least part of the thin barrier of dielectric structural material that isolates the at least two elements from one another, by depositing a thin barrier of the dielectric structural material to a region selected from the group consisting of: (a) lateral portions of the layer that will locate the dielectric structural material directly or indirectly on at least a portion of the sidewalls of the metal structural material of one of the at least two elements wherein the dielectric structural material forms a thin barrier, (2) at least a portion of an up-facing surface of the metal structural material of one of the at least two elements that might otherwise contact a down-facing surface of another of the at least two elements, and (3) at least a portion of a down-facing surface of the metal structural material of one of the at least two elements that might otherwise contact an up-facing surface of another of the at least two elements,
(3) after forming each of the plurality of layers, separating the sacrificial material from the metal structural material and the dielectric structural material on each layer to reveal the multi-layer three dimensional structure,
wherein the thin barrier of dielectric material has a thickness less than the layer thickness as measured along a normal to a surface of the metal structural material that is being bounded by the dielectric material, and
wherein each successive layer of the plurality of layers represents a successive cross-section of the three-dimensional structure.

31. The method of claim 30 wherein the sacrificial material is a metal material and a first layer of the plurality of layers is formed on a substrate and wherein the structure is released from the substrate after formation.

32. The method of claim 30 wherein the sacrificial material is a metal material and a first layer of the plurality of layers is formed on a substrate and wherein the structure remains attached to the substrate when the structure is put into use.

33. The method of claim 30 wherein the thin barrier of dielectric structural material has a thickness selected from the group consisting of (a) less than 50% of the layer thickness, (b) less than 25% of the layer thickness, and (c) less than 10% of the layer thickness.

34. The method of claim 30 wherein the metal structural material is a different metal material on two different layers.

35. The method of claim 30 wherein the depositing of the metal structural material is selected from the group consisting of: (a) electroplating and (b) electroless plating.

36. The method of claim 30 wherein a seed layer material is deposited onto the dielectric material prior to deposition of the metal structural material.

37. The method of claim 36 wherein the seed layer material is selected from the group consisting of (1) a single seed layer material and (2) an adhesion layer/seed layer combination of materials.

38. The method of claim 30 additionally comprising converting a three-dimensional computer data representation of the at least two components of the structure into a plurality of two-dimensional layer representations, each having a layer thickness and performing a plurality of Boolean layer comparison operations.

39. The method of claim 30 wherein the formation of the at least one of the plurality of successively deposited and adhered multi-material layers comprises a deposition order of (1)(a) for one of the at least two elements, deposition of the dielectric structural material, (1)(a) for another of the at least two elements, (1)(b), and then (1)(c).
